(19) United States
(12) Patent Application Publication
(10) Pub. No.: US 2024/0120202 A1
(43) Pub. Date: Apr. 11, 2024

(54) Implanted Regions for Semiconductor Structures with Deep Buried Layers

(71) Applicant: Wolfspeed, Inc., Durham, NC (US)

(72) Inventors: Scott Sheppard, Chapel Hill, NC (US); Kyle Bothe, Cary, NC (US); Chris Michael Hardiman, Cary, NC (US)

(21) Appl. No.: 17/961,032

(22) Filed: Oct. 6, 2022

(51) Int. Cl. H01L 21/265; H01L 21/225; H01L 21/74

(52) U.S. Cl. CPC H01L 21/26553; H01L 21/2253; H01L 21/74

(57) ABSTRACT

Semiconductor devices are provided. In one example, a semiconductor device includes a semiconductor structure having a buried layer at a depth of about 275 Angstroms or greater (e.g., about 500 Angstroms or greater) from a surface of the semiconductor structure. The semiconductor device includes an implanted region extending at least partially through the semiconductor structure and into the buried layer. The implanted region includes a distribution of implanted dopants of a first conductivity type extending into the buried layer. The semiconductor device includes an electrode on the implanted region. In some examples, the semiconductor structure may include an N-polar Group III-nitride semiconductor structure.

### FIELD

The present disclosure relates generally to semiconductor devices.

### BACKGROUND

Power semiconductor devices are widely used to carry large currents, support high voltages and/or operate at high frequencies such as radio frequencies. A wide variety of power semiconductor devices are available for different applications including, for example, power switching devices and power amplifiers. Many power semiconductor devices are implemented using various types of field effect transistors (FETs) devices including MOSFETs (metal-oxide semiconductor field-effect transistors), DMOS (double-diffused metal-oxide semiconductor) transistors, HEMTs (high electron mobility transistors), MESFETs (metal-semiconductor field-effect transistors), LDMOS (laterally diffused metal-oxide semiconductor) transistors, etc.

Power semiconductor devices may be fabricated from wide band gap semiconductor materials (e.g., having a band-gap greater than 1.40 eV). For example, power HEMTs may be fabricated from gallium nitride (GaN) or other Group III nitride-based material systems that are formed, for instance, on a silicon carbide (SiC) substrate or other substrate. As used herein, the term “Group III nitride” refers to those semiconducting compounds formed between nitrogen and the elements in Group III of the periodic table, usually aluminum (Al), gallium (Ga), and/or indium (In). These compounds have empirical formulas in which one mole of nitrogen is combined with a total of one mole of the Group III elements. For high power, high temperature, and/or high frequency applications, devices formed in wide band gap semiconductor materials such as silicon carbide (e.g., 2.996 eV band gap for alpha silicon carbide at room temperature) and the Group III-nitrides (e.g., 3.36 eV band gap for gallium nitride at room temperature) may provide higher electric field breakdown strengths and higher electron saturation velocities as compared to gallium arsenide (GaAs) and silicon (Si) based devices.

### SUMMARY

Aspects and advantages of embodiments of the present disclosure will be set forth in part in the following description, or may be learned from the description, or may be learned through practice of the embodiments.

One example aspect of the present disclosure is directed to a semiconductor device. The semiconductor device includes a semiconductor structure having a buried layer at a depth of about 275 Angstroms or greater (e.g., about 500 Angstroms or greater) from a surface of the semiconductor structure. The semiconductor device includes an implanted region extending at least partially through the semiconductor structure and into the buried layer. The implanted region includes a distribution of implanted dopants of a first conductivity type extending into the buried layer. The semiconductor device includes an electrode on the implanted region.

Another example aspect of the present disclosure is directed to a transistor device. The transistor device includes an N-polar Group III-nitride semiconductor structure having an N face at a surface of the semiconductor structure. The semiconductor structure includes a buried channel layer. The semiconductor structure includes a confining layer on a first surface of the buried channel layer. The semiconductor structure includes a barrier layer on a second surface of the buried channel layer. The transistor device includes an implanted region extending at least partially through the confining layer and into the buried channel layer. The implanted region includes a distribution of implanted dopants of a first conductivity type extending into the buried channel layer. The implanted region includes an electrode on the implanted region.

Another example aspect of the present disclosure is directed to a transistor device. The transistor device includes an N-polar Group III-nitride semiconductor structure having an N-face at a surface of the semiconductor structure. The transistor device includes a source contact. The transistor device includes a drain contact. The transistor device includes a gate contact. The N-polar Group III-nitride semiconductor structure includes a barrier layer, a channel layer on the barrier layer, a confining layer on the channel layer, and a cap layer on the confining layer. The transistor device includes an atomic layer etch (ALE) defined recess in the N-polar Group III-nitride semiconductor structure.

Another example aspect of the present disclosure is directed to a method of forming a semiconductor device. The method includes forming a semiconductor structure having a buried layer and one or more confining layers. The buried layer is at a depth of about 275 Angstroms or greater (e.g., 500 Angstroms or greater) from a surface of the semiconductor structure. The method includes implanting dopants into the semiconductor structure to form an implanted region in the semiconductor structure. The implanted region extends at least partially through the semiconductor structure and into the buried layer. The implanted region includes a distribution of implanted dopants of a first conductivity type extending into the buried layer.

These and other features, aspects and advantages of various embodiments will become better understood with reference to the following description and appended claims. The accompanying drawings, which are incorporated in and constitute a part of this specification, illustrate embodiments of the present disclosure and, together with the description, explain the related principles.

### BRIEF DESCRIPTION OF THE DRAWINGS

Detailed discussion of embodiments directed to one of ordinary skill in the art are set forth in the specification, which refers to the appended figures, in which:

FIG. 1 depicts an example transistor device according to example embodiments of the present disclosure.

FIG. 2 depicts a close-up view of an implanted region of an example semiconductor device according to example embodiments of the present disclosure.

FIG. 3 depicts an example transistor device according to example embodiments of the present disclosure.

FIG. 4 depicts a close-up view of an implanted region of an example semiconductor device according to example embodiments of the present disclosure.

FIGS. 5A-5I depict example fabrication of a semiconductor device according to example embodiments of the present disclosure.

FIG. 6A-6B depict example fabrication of a semiconductor device according to example embodiments of the present disclosure.

### DETAILED DESCRIPTION

Reference now will be made in detail to embodiments, one or more examples of which are illustrated in the drawings. Each example is provided by way of explanation of the embodiments, not limitation of the present disclosure. In fact, it will be apparent to those skilled in the art that various modifications and variations may be made to the embodiments without departing from the scope or spirit of the present disclosure. For instance, features illustrated or described as part of one embodiment may be used with another embodiment to yield a still further embodiment. Thus, it is intended that aspects of the present disclosure cover such modifications and variations.

Semiconductor devices may be used in power electronics applications. For instance, transistor devices, such as high electron mobility transistors (HEMTs), may be used in power electronics applications. HEMTs fabricated in Group III-nitride based material systems may have the potential to generate large amounts of radio frequency (RF) power because of the combination of material characteristics that includes high breakdown fields, wide band gaps, large conduction band offset, and/or high saturated electron drift velocity. As such, Group III-Nitride based HEMTs may be promising candidates for high frequency and/or high-power RF applications (as well as for low frequency high power switching applications) as discrete transistors or as coupled with other circuit elements, such as in monolithic microwave integrated circuit (MIMIC) devices.

Field effect transistors such as HEMT devices may be classified into depletion mode and enhancement mode types, corresponding to whether the transistor is in an ON-state or an OFF-state at a gate-source voltage of zero. In enhancement mode devices, the devices are OFF at zero gate-source voltage, whereas in depletion mode devices, the device is ON at zero gate-source voltage. Often, high performance Group III nitride-based HEMT devices may be implemented as depletion mode (normally-on) devices, in that they are conductive at a gate-source bias of zero due to the polarization-induced charge at the interface of the barrier and channel layers of the device.

When an HEMT device is in an ON-state, a two-dimensional electron gas (2DEG) is formed at the heterojunction of two semiconductor materials with different band gap energies, where the smaller band gap material has a higher electron affinity. The 2DEG is an accumulation layer in the smaller band gap material and may include a very high sheet electron concentration. Additionally, electrons that originate in the wider-band gap semiconductor material transfer to the 2DEG layer, allowing high electron mobility due to reduced ionized impurity scattering. This combination of high carrier concentration and high carrier mobility may give the HEMT device a very large transconductance (which may refer to the relationship between output current and input voltage) and may provide a strong performance advantage over MOSFETs for high-frequency applications.

Certain semiconductor devices may include a semiconductor structure having a buried layer (e.g., a buried conductive layer) that is buried at a significant depth below a top surface of the semiconductor structure. For instance, semiconductor devices may include an N-polar Group III-nitride semiconductor structure with an N-face located at the top surface of the semiconductor structure. These semiconductor devices may include a buried conductive layer (e.g., a channel layer) located deep beneath the top surface of the semiconductor structure, such as at a depth of about 275 Angstroms or greater, such as about 500 Angstroms or greater, such as in a range of about 275 Angstroms to about 1000 Angstroms. In many applications, it may be desirable to include an electrode providing an ohmic contact with a low resistance path to the buried conductive layer. As used herein, the term “ohmic contact” refers to a non-rectifying contact that has a contact resistance of about 1 ohm-mm or less.

According to aspects of the present disclosure, an implanted region may be formed in the semiconductor structure using an ion implantation process. The implanted region may extend through the semiconductor structure and into the buried layer. For instance, the implanted region may extend to a depth of about 275 Angstroms or greater, such as about 500 Angstroms or greater, such as in a range of about 275 Angstroms to about 1000 Angstroms. The implanted region may include a distribution of implanted dopants of a first conductivity type extending into the buried layer such that the implanted region is an n-type implanted region. An electrode (e.g., an ohmic contact) may be formed on the implanted region. The implanted dopants may provide an implant profile that provides a desired sheet resistivity to permit low resistance ohmic contact between an electrode and the buried conductive layer. For instance, the implanted region may have a resistivity in a range of about 0.2 Ohms-mm or less.

In some examples, the implanted region may include an implant profile having a distribution of implanted dopants in the implanted region such that a peak dopant concentration (e.g., the highest concentration of dopants in the implant profile) is at a depth in the implanted region that is within about 50 Angstroms or less of the buried layer. In some examples, the peak dopant concentration may be at a depth that is within the buried layer. The peak dopant concentration may be, for instance, about 1×10¹⁸ ions/cm³ or greater, such as about 5×10²⁰ ions/cm³ or greater.

In some examples, the semiconductor device may be a transistor device. The transistor device may be an HEMT device having an N-polar Group III-nitride semiconductor structure despised on a substrate, such as a silicon carbide substrate. The N-polar Group III-nitride semiconductor structure may have an N-face at a top surface of the semiconductor structure.

The N-polar Group III-nitride semiconductor structure may include a channel layer that is deeply buried beneath the top surface of the semiconductor structure, such as at a depth of about 275 Angstroms or greater, such as about 500 Angstroms or greater, such as in a range of about 275 Angstroms to about 1000 Angstroms. The channel layer may be, for instance, a GaN layer. The channel layer may be on a first confining layer. The first confining layer may be a barrier layer (e.g., a back barrier layer) having a different band gap than the band gap of the channel layer. The first confining layer may be, for instance, an AlGaN layer or a multilayer structure including an AlGaN layer. A 2DEG may be formed at an interface between the channel layer and the first confining layer such that the 2DEG is also buried deeply within the semiconductor structure.

The N-polar Group III-nitride semiconductor structure may include a second confining layer on the channel layer. The second confining layer may have a different band gap than the band gap of the channel layer. The second confining layer may be, for instance, an AlGaN layer. The N-polar Group III-nitride may include a thick cap layer on the second confining layer. The thick cap layer may be, for instance, a GaN layer. The thick cap layer may have a thickness, for instance, in a range of about 250 Angstroms to about 1000 Angstroms.

The thick cap layer in transistor devices including an N-polar Group III-nitride semiconductor structure buries the channel layer and the 2DEG for the transistor device deep below the surface of the semiconductor structure. By burying the channel layer and 2DEG deep below the surface of the semiconductor structure, trapping and other surface effects on the 2DEG may be mitigated by physically moving the 2DEG a larger distance away from the surface of the semiconductor structure. In addition, the increased thickness of the cap layer may provide for increased polarization of the semiconductor structure at the interface between the channel layer and the first confining layer (e.g., the back barrier layer). The back barrier layer may be modified to control the channel layer charge density independent of the gate-to-channel layer distance. The thick cap layer for N-polar Group III-nitride semiconductor materials may provide for increased charge at the interface between the channel layer and the first confining layer, increasing carrier concentration and electron mobility of the 2DEG. This may lead to enhanced transconductance of the 2DEG and improved performance of the transistor device. For instance, the increased transconductance may provide for a lower on-resistance of the transistor device as well as suitability for use at higher frequencies, such as mm-wave frequencies or higher.

According to example aspects of the present disclosure, the transistor device having the N-polar Group III-nitride semiconductor structure may include an implanted region to provide an ohmic contact between an electrode (e.g., a source contact and/or a drain contact) and the buried channel layer. The implanted region may include implanted dopants of a first conductivity type. The implanted region may extend through the N-polar Group III-nitride semiconductor structure and into the buried layer. For instance, the implanted region may extend to a depth of about 275 Angstroms or greater, such as about 500 Angstroms or greater, such as in a range of about 275 Angstroms to about 1000 Angstroms beneath the surface of the semiconductor structure. The implanted dopants may be silicon (Si), germanium (Ge), sulfur (S), and/or oxygen (O) ions. The electrode (e.g., the source contact and/or the drain contact) may be on the implanted region.

In some examples, the transistor device may include a gate contact extending at least partially through the N-polar Group III-nitride semiconductor structure. For instance, the gate contact may extend through the thick cap layer. In some examples, the gate contact may be formed in a trench defined in the thick cap layer. The trench may be formed, for instance, using atomic layer etch (ALE) such that the trench is an ALE defined trench. The trench may be formed using other suitable etching processes, such as a plasma-based dry etch process (e.g., using a pulsed plasma or a continuous plasma).

In some examples, the transistor device may include one or more passivation layers. The passivation layers may include, for instance, a SiN layer or other suitable dielectric layer. The one or more passivation layers may be formed on the gate contact and/or on the top surface of the semiconductor structure. In some examples, the one or more passivation layers may be formed using an atomic layer deposition (ALD) process, sputter deposition process, or other suitable deposition process.

Examples of the present disclosure are directed to a method of fabrication of a semiconductor device, such as a transistor device having an N-polar Group III-nitride semiconductor structure. The method may include, for instance, forming a semiconductor structure (e.g., using epitaxial growth) on a substrate. The semiconductor structure may be an N-polar Group III-nitride semiconductor structure. The semiconductor structure may include a buried layer (e.g., a channel layer) at a depth of about 275 Angstroms or greater from the surface of the semiconductor structure, such as about 500 Angstroms or greater from the surface of the semiconductor structure, such as in a range of about 275 Angstroms to about 1000 Angstroms from the surface of the semiconductor structure.

The method may include implanting ions (e.g., using an ion implantation process) to form an implanted region in the semiconductor structure. The implanted region may extend through the semiconductor structure and into the buried layer. The implanted region may include a distribution of implanted dopants of a first conductivity type extending into the buried layer such that the implanted region is an n-type region. The implant conditions may be selected to provide an implant profile having a distribution of implanted dopants in the implanted region such that a peak dopant concentration is at a depth in the implanted region that is within about 50 Angstroms or less of the buried layer. In some examples, the peak dopant concentration may be at a depth that is within the buried layer. The implant conditions may be selected to provide a peak dopant concentration of about 1×10¹⁸ ions/cm³ or greater, such as about 5×10²⁰ ions/cm³ or greater.

The method may include forming an electrode on the implanted region. The electrode may provide an ohmic contact between the electrode and the semiconductor structure. The electrode may be, for instance, a drain contact or a source contact of a transistor device. The implanted region may provide a low resistance path between the ohmic contact and the buried layer.

In some examples, prior to implanting ions into the semiconductor structure, the method may include etching at least a portion of the semiconductor structure to form a recess in the semiconductor structure. The etching may be performed using an ALE process such that the recess is an ALE defined recess. In addition, or in the alternative, the etching may be performed using a plasma-based dry etch process (e.g., using a pulsed plasma or a continuous plasma). The etching process may be used to form a mesa in the semiconductor structure with two recesses on either side of the mesa. A ledge may be formed at in the semiconductor structure at the bottom of the recess. After etching the recess, ions may be implanted into the portion of the semiconductor structure located below the recess to form the implanted region. This may facilitate implanting ions such that the implanted region extends deeply into the buried layer.

Examples of the present disclosure provide technical effects and benefits. For instance, the implanted region may provide for a low-resistance connection through a thick semiconductor structure to the buried layer. Use of ion implantation may be preferred over other methods of forming low-resistance regions (e.g., n+ GaN re-growth) because ion implantation is more repeatable and controllable during semiconductor fabrication. In addition, the use of other methods of forming low-resistance regions, such as n+ GaN re-growth, may require the use of an epitaxial reactor as an intermediate process step to form the low-resistance regions, leading to increased complexity and processing time during the device fabrication process.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein.

It will be understood that when an element such as a layer, region, or substrate is referred to as being “on” or extending “onto” another element, it may be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “lateral” or “vertical” may be used herein to describe a relationship of one element, layer or region to another element, layer or region as illustrated in the figures. It will be understood that these terms are intended to encompass different orientations of the device in addition to the orientation depicted in the figures.

Embodiments of the disclosure are described herein with reference to cross-section illustrations that are schematic illustrations of idealized embodiments (and intermediate structures) of the invention. The thickness of layers and regions in the drawings may be exaggerated for clarity. Additionally, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. Similarly, it will be understood that variations in the dimensions are to be expected based on standard deviations in manufacturing procedures. As used herein, “approximately” or “about” includes values within 10% of the nominal value.

Like numbers refer to like elements throughout. Thus, the same or similar numbers may be described with reference to other drawings even if they are neither mentioned nor described in the corresponding drawing. Also, elements that are not denoted by reference numbers may be described with reference to other drawings.

Some embodiments of the invention are described with reference to semiconductor layers and/or regions which are characterized as having a conductivity type such as n type or p type, which refers to the majority carrier concentration in the layer and/or region. Thus, N type material has a majority equilibrium concentration of negatively charged electrons, while P type material has a majority equilibrium concentration of positively charged holes. Some material may be designated with a “+” or “—” (as in N+, N−, P+, P−, N++, N−−, P++, P−−, or the like), to indicate a relatively larger (“+”) or smaller (“−”) concentration of majority carriers compared to another layer or region. However, such notation does not imply the existence of a particular concentration of majority or minority carriers in a layer or region.

Aspects of the present disclosure are discussed with reference to an HEMT transistor device for purposes of illustration and discussion. Those of ordinary skill in the art, using the disclosures provided herein, will appreciate that certain aspects of the present disclosure may be applicable to other semiconductor devices without deviating from the scope of the present disclosure, such as Schottky rectifiers.

In the drawings and specification, there have been disclosed typical embodiments and, although specific terms are employed, they are used in a generic and descriptive sense only and not for purposes of limitation of the scope set forth in the following claims.

With reference now to the Figures, example embodiments of the present disclosure will now be set forth.

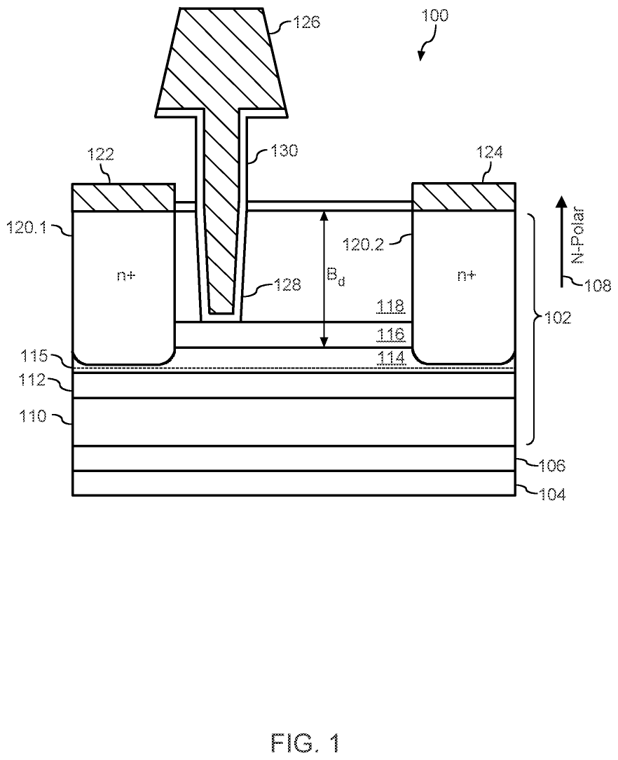

FIG. 1 depicts a cross-sectional view of an example HEMT device 100 according to example embodiments of the present disclosure. FIG. 1 is intended to represent structures for identification and description and is not intended to represent the structures to physical scale. The HEMT device 100 may include a semiconductor structure 102. The semiconductor structure 102 may be a Group III-nitride semiconductor structure, such as an N-polar Group III-nitride semiconductor structure.

As used herein, the term “Group III nitride” refers to those semiconducting compounds formed between nitrogen (N) and the elements in Group III of the periodic table, usually aluminum (Al), gallium (Ga), and/or indium (In). The term also refers to ternary and quaternary (or higher) compounds such as, for example, AlGaN and AlInGaN. As is well understood by those in this art, the Group III elements may combine with nitrogen to form binary (e.g., GaN), ternary (e.g., AlGaN, AlInN), and quaternary (e.g., AlInGaN) compounds. These compounds all have empirical formulas in which one mole of nitrogen is combined with a total of one mole of the Group III elements. As used herein, the term “N-polar Group III-nitride” refers to a Group III-nitride semiconductor structure having an outward facing nitrogen face “N-face” in the growth direction (e.g., epitaxial growth direction) of the semiconductor structure.

The semiconductor structure 102 may be on a substrate 104. The substrate 104 may be a semiconductor material. For instance, the substrate 104 may be a silicon substrate, a silicon carbide (SiC) substrate, a sapphire substrate, or other suitable substrate. In some embodiments, the substrate 104 may be a semi-insulating SiC substrate that may be, for example, the 4H polytype of silicon carbide. Other SiC candidate polytypes may include the 3C, 6H, and 15R polytypes. The substrate may be a High Purity Semi-Insulating (HPSI) substrate, available from Wolfspeed, Inc. The term “semi-insulating” is used descriptively herein, rather than in an absolute sense.

In some embodiments, the SiC bulk crystal of the substrate 104 may have a resistivity equal to or higher than about 1×10⁵ ohm-cm at room temperature. Example SiC substrates that may be used in some embodiments are manufactured by, for example, Wolfspeed, Inc., and methods for producing such substrates are described, for example, in U.S. Pat. No. Re. 34,861, U.S. Pat. Nos. 4,946,547, 5,200,022, and 6,218,680, the disclosures of which are incorporated by reference herein. Although SiC may be used as a substrate material, embodiments of the present disclosure may utilize any suitable substrate, such as sapphire (Al₂O₃), aluminum nitride (AlN), aluminum gallium nitride (AlGaN), gallium nitride (GaN), silicon (Si), GaAs, LGO, zinc oxide (ZnO), LAO, indium phosphide (InP), and the like. The substrate 104 may be a SiC wafer, and the HEMT device 100 may be formed, at least in part, via wafer-level processing, and the wafer may then be diced to provide a plurality of individual HEMT devices 100. In some embodiments, the substrate 104 of the HEMT device 100 may be a thinned substrate 104. In some embodiments, the thickness of the substrate 104 may be about 100 μm or less, such as about 75 μm or less, such as about 50 μm or less.

The HEMT device 100 may include an optional nucleation layer 106 located between the semiconductor structure 102 and the substrate 104. The nucleation layer 106 may be, for instance, a GaN layer and/or an AlN layer on the substrate 104 to provide a crystal structure transition between, for instance, a SiC substrate 104 and the Group III-nitride semiconductor structure 102. The nucleation layer 106 may be deposited on the substrate 104 using, for instance, metal-organic chemical vapor deposition (MOCVD), molecular beam epitaxy (MBE), or hydride vapor phase epitaxy (HYPE).

The semiconductor structure 102 may be an N-polar Group III-nitride semiconductor structure with an outward N-face in the growth direction 108 of the semiconductor structure 102. The semiconductor structure 102 may include several layers. In the example HEMT device 100 of FIG. 1, the semiconductor structure includes a buffer layer 110, a first confining layer 112, a channel layer 114, a second confining layer 116, and a cap layer 118. However, those of ordinary skill in the art, using the disclosures provided herein, will understand that aspects of the present disclosure are applicable to devices having semiconductor structures with different layer arrangements, such as devices with Ga-polar semiconductor structures. The semiconductor structure 102 may be formed by epitaxial growth on the substrate 104 and optional nucleation layer 106. Techniques for epitaxial growth of Group III-nitrides have been described in, for example, U.S. Pat. Nos. 5,210,051, 5,393,993, and 5,523,589, the disclosures of which are incorporated by reference herein.

The buffer layer 110 may be an N-polar Group III nitride, such as AlᵥGa₁₋ᵥN, where 0≤v<0.1. In some embodiments, the aluminum mole fraction v is approximately 0 (e.g., 0.05 or less), indicating that the buffer layer 110 is GaN. The buffer layer 110 may or may not include other Group III-nitrides such as InGaN, AlInGaN or the like. The buffer layer 110 may be undoped and may be grown to a thickness in the range of about 0.5 μm to about 5 μm, such as about 2 μm. The buffer layer 110 may be a multi-layer structure, such as a superlattice or combinations of GaN, AlGaN or the like. The buffer layer 110 may be under compressive strain in some embodiments.

The semiconductor structure 102 may include the first confining layer 112 on the buffer layer 110. The first confining layer 112 may be an N-polar Group III nitride, such as Al_{w}Ga_{1-w}N where 0.1≤w<0.4, indicating that the first confining layer 112 is an AlGaN layer. In some embodiments, the first confining layer 112 may be a ScAlN layer or a ScAlGaN layer. The first confining layer 112 may or may not include other Group III-nitrides such as InGaN, AlInGaN or the like. The first confining layer 112 may act as a back barrier layer or barrier layer for the HEMT device 100. The first confining layer 112 may have a different band gap relative to the channel layer 114. The first confining layer 112 may have a thickness in a range of about 250 Angstroms to about 350 Angstroms, such as about 300 Angstroms.

In some embodiments, the first confining layer 112 may be a multilayer structure. For instance, in one example, the first confining layer 112 may include a first layer of n+ doped GaN with a thickness of about 100 Angstroms. The first confining layer 112 may include a second layer of graded Al_{w.1}Ga_{1-w.1}N on the first layer, where w.1 varies from about 0.05 to about 0.4. The second layer of graded Al_{w}Ga_{1-w}N may have a thickness of about 100 Angstroms. The first confining layer 112 may include a third layer of Al_{w.2}Ga_{1-w.2}N on the second layer, where w.2 is in a range of 0.3 to 0.4. The thickness of the third layer is about 100 Angstroms. The first confining layer 112 may include a fourth layer of AlN on the third layer. The thickness of the fourth layer may be in a range of about 5 Angstroms to about 15 Angstroms, such as about 7 Angstroms.

The semiconductor structure 102 may include the channel layer 114 on the first confining layer 112 (back barrier layer). The channel layer 114 may be an N-polar Group III-nitride, such as AlₓGa₁₋ₓN, where 0≤x<0.1, provided that the energy of the conduction band edge of the channel layer 114 is less than the energy of the conduction band edge of the first confining layer 112 at the interface between the channel layer 114 and the first confining layer 112. The channel layer 114 may have a band gap that is different than the band gap of the first confining layer 112. In some embodiments, the aluminum mole fraction x is approximately 0 (e.g., 0.05 or less), indicating that the channel layer 114 is GaN. The channel layer 114 may or may not include other Group III-nitrides such as InGaN, AlInGaN or the like. The channel layer 114 may have a thickness in a range of about 75 Angstroms to about 125 Angstroms, such as about 100 Angstroms.

A 2DEG 115 may be induced in the channel layer 114 at the interface between the channel layer 114 and the first confining layer 112 (barrier layer). The 2DEG 115 is highly conductive and allows conduction between the source and drain regions of the HEMT device 100. The 2DEG 115 may be controlled under operation of a gate, such that the HEMT device 100 acts as a controllable transistor device.

The semiconductor structure 102 includes a second confining layer 116 (e.g., an AlGaN cap layer) on the channel layer 114. The second confining layer 116 may be an N-polar Group III-nitride, such as Al_{y}Ga_{1-y}N where 0.1≤y<0.4, indicating that the second confining layer 116 is an AlGaN layer. In some embodiments, the aluminum mole fraction y is in a range of about 0.2 to about 0.3. In some embodiments, the second confining layer 116 may be a ScAlN layer or a ScAlGaN layer. The second confining layer 116 may or may not include other Group III-nitrides such as InGaN, AlInGaN or the like. The second confining layer may have a band gap that is different than the band gap of the channel layer 114. The second confining layer 116 may have a thickness in a range of about 15 Angstroms to about 50 Angstroms, such as about 26 Angstroms.

The semiconductor structure 102 includes a thick cap layer 118 on the second confining layer 116. The thick cap layer 118 may be an N-polar Group III-nitride, such as Al_{z}Ga_{1-z}N, where 0≤z<0.1. In some embodiments, the aluminum mole fraction x is approximately 0 (e.g., 0.05 or less), indicating that the channel layer 114 is a GaN layer. The cap layer 118 may or may not include other Group III-nitrides such as InGaN, AlInGaN or the like. The thick cap layer 118 buries the channel layer 114 deep below the surface of semiconductor structure 102 such that the channel layer 114 is a buried layer at a depth Bd of about 275 Angstroms or greater from the surface of the semiconductor structure 102, such as about 500 Angstroms or greater from the surface of the semiconductor structure 102, such as in a range of about 275 Angstroms to about 1000 Angstroms from the surface of the semiconductor structure 102. The thick cap layer 118 may have a thickness in a range of about 250 Angstroms to about 1000 Angstroms, such as about 500 Angstroms.

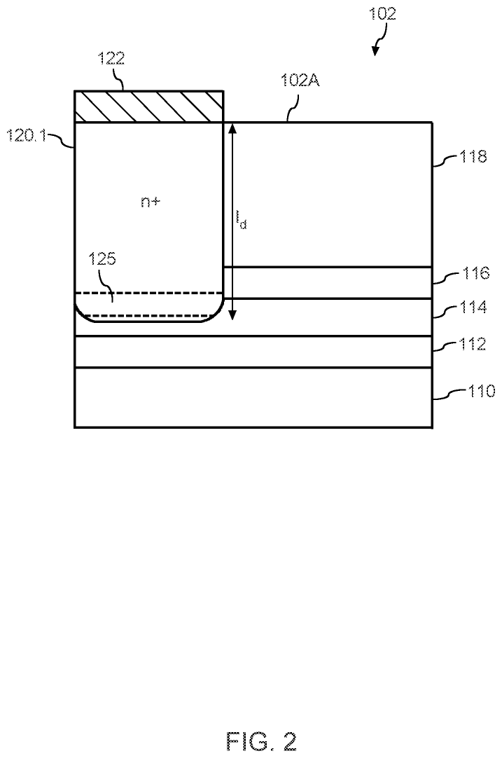

The semiconductor structure 102 includes implanted regions 120.1 and 120.2. The implanted regions 120.1 and 120.2 include a distribution of implanted dopants (e.g., ions) of a first conductivity type such that the implanted regions 120.1 and 120.2 are n-type regions. The implanted regions 120.1 and 120.2 extend through the semiconductor structure 102 and into the channel layer 114. Details concerning the implanted regions 120.1 and 120.2 will be discussed with reference to FIG. 2 below.

The HEMT device 100 includes electrodes on the implanted regions 120.1 and 120.2. More particularly, the HEMT device 100 may include a source contact 122 on the implanted region 120.1. The HEMT device 100 may include a drain contact 124 on the implanted region 120.2. The source contact 122 and the drain contact 124 may be laterally spaced apart from each other. In some embodiments, the source contact 122 and the drain contact 124 may include a metal that may form an ohmic contact to a Group III-nitride based semiconductor material. Suitable metals may include refractory metals, such as titanium (Ti), tungsten (W), titanium tungsten (TiW), silicon (Si), titanium tungsten nitride (TiWN), tungsten silicide (WSi), rhenium (Re), niobium (Nb), Ni, gold (Au), aluminum (Al), tantalum (Ta), molybdenum (Mo), NiSiₓ, titanium silicide (TiSi), titanium nitride (TiN), tungsten silicon nitride (WSiN), platinum (Pt) and the like. In some embodiments, the source contact 122 may be an ohmic contact. The drain contact 124 may be an ohmic contact. In some embodiments, the source contact 122 and/or the drain contact 124 may include a plurality of layers to form an ohmic contact that may be provided as described, for example, in U.S. Pat. Nos. 8,563,372 and 9,214,352, the disclosures of which are incorporated by reference herein.

The HEMT device 100 may include a gate contact 126. The gate contact 126 may extend at least partially through a trench (e.g., an ALE defined trench) in the cap layer 118 so that the gate contact 126 is proximate to the second confining layer 116. In some examples, the gate contact 126 may have a gate length LG in a range of about 50 nm to about 150 nm. The gate length is the length of the gate contact 126 proximate to the second confining layer 116.

A passivation layer 128 may be located between the gate contact 126 and the second confining layer 116. The passivation layer 128 may be SiN. Other suitable dielectric layers may be used as the passivation layer 128, such as SiO₂, MgOx, MgNx, ZnO, SiNx, SiOx or other dielectric layers. The passivation layer 128 may be formed, for instance, using MOCVD process(s), atomic layer deposition (ALD) process(s), and/or sputter deposition processes. The passivation layer 128 may serve as a gate dielectric. In some examples, the passivation layer 128 may have a thickness, for instance, of about 5 Angstroms to about 100 Angstroms, such as about 10 Angstroms to about 50 Angstroms.

The gate contact 126 may be a T-shaped gate or a gamma gate, the formation of which is discussed by way of example in U.S. Pat. Nos. 8,049,252, 7,045,404, and 8,120,064, the disclosures of which are incorporated by reference herein. The material of the gate contact 126 may be chosen based on the composition of the second confining layer 116. Materials capable of making a contact (e.g., a Schottky contact) to a Group III-nitride based semiconductor material may be used, such as, for example, nickel (Ni), platinum (Pt), nickel silicide (NiSiₓ), copper (Cu), palladium (Pd), chromium (Cr), tungsten (W) and/or tungsten silicon nitride (WSiN).

The HEMT device 100 may include additional passivation layer(s) 130 on the semiconductor structure 102, the gate contact 126, and/or other structures of the HEMT device 100. The additional passivation layer(s) 130 may be, for instance, dielectric materials, such as SiO₂, MgOx, MgNx, ZnO, SiNx, SiOx, alloys or layer sequences thereof. The additional passivation layer(s) 130 may be formed using MOCVD process(s), ALD process(s), sputter deposition process(s), or other suitable process(s). One or more insulating layers (not shown) may be on the HEMT device 100. For instance, the HEMT device 100 may be encapsulated in an insulating material without deviating from the scope of the present disclosure.

A transistor may be formed by the active region between the source contact 122 and the drain contact 124 under the control of a gate contact 126 between the source contact 122 and the drain contact 124. FIG. 1 depicts a cross-sectional view of one unit of an HEMT device 100 for purposes of illustration. The HEMT device 100 may be formed adjacent to additional HEMT device units and may share, for instance, a source contact 122 with adjacent HEMT device units.

In some examples, the HEMT device 100 may be operable at frequencies of up to about 150 GHz. For instance, the HEMT device 100 may be operable at a frequency in a range of about 10 GHz to about 150 GHz, such as in a range of about 30 GHz to about 150 GHz, such as in a range of about 50 GHz to about 150 GHz. In some examples, the HEMT device 100 may have a power density of up to 10 W/mm or greater in these frequency ranges, such as a power density in a range of 2.5 W/mm to about 12 W/mm.

FIG. 2 depicts a close-up cross-sectional view of an example implanted region, such as implanted region 120.1 in the semiconductor structure 102 of the HEMT device 100 of FIG. 1, according to example embodiments of the present disclosure. FIG. 2 is intended to represent structures for identification and description and is not intended to represent the structures to physical scale.

The implanted region 120.1 includes a distribution of implanted dopants extending into the buried channel layer 114. The implanted dopants may be of a first conductivity type such that the implanted region 120.1 is an n-type region. The implanted dopants may be, for instance, silicon, germanium, sulfur, and/or oxygen ions. The implanted region 120.1 may have a distribution of implanted dopants that extends to a depth Id from the surface 102A of the semiconductor structure. The depth Id may be about 275 Angstroms or greater, such as about 500 Angstroms or greater, such as in a range of about 275 Angstroms to about 1000 Angstroms. The distribution of implanted dopants may extend through the cap layer 118, the second confining layer 116 and to the buried channel layer 114. In some embodiments, the distribution of implanted dopants may extend into the first confining layer 112 (back barrier layer) and/or into the buffer layer 110 of the semiconductor structure.

The implanted region 120.1 may have a peak dopant concentration of 1×10¹⁸ ions/cm³ or greater. For example, in some embodiments, the dose and energy of the implants may be selected to provide a peak dopant concentration of about 5×10²⁰ ions/cm³ in the implanted region 120.1. The distribution of implanted dopants in the implanted region 120.1 may have its peak dopant concentration at a depth in the implanted region 120.1 close to the buried channel layer 114 of the semiconductor structure 102. For instance, the peak dopant concentration may be in a region 125 within the implanted region 120.1. The region 125 may be within 50 Angstroms or less of the buried channel layer 114. In some examples, the region 125 may be within the buried channel layer 114. In some examples, the distribution of implanted dopants may provide a substantially uniform concentration of implanted dopants throughout the implanted region 120.1 of the semiconductor structure 102.

As shown in FIG. 2, an electrode (e.g., the source contact 122) is formed on the implanted region 120.1. The electrode may form an ohmic contact with the implanted region 120.1. The implanted dopants within the implanted region 120.1 may provide a low resistive path between the ohmic source contact 122 and the buried channel layer 114. For instance, the implanted region 120.1 may have a dopant concentration such that the implanted region 120.1 has a resistivity in a range of about 0.2 Ohms-mm or less.

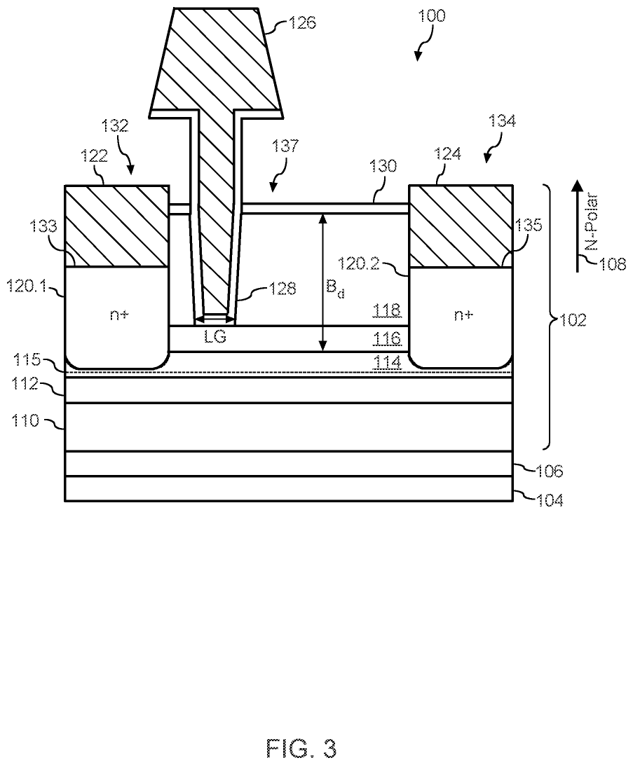

FIG. 3 depicts a cross-sectional view of an example HEMT device 100 according to example embodiments of the present disclosure. FIG. 3 is intended to represent structures for identification and description and is not intended to represent the structures to physical scale. The HEMT device 100 of FIG. 3 is similar to the HEMT device 100 of FIG. 1, except that the implanted regions 120.1 and 120.2 are formed beneath recesses in the semiconductor structure 102.

More particularly, the semiconductor structure 102 may be etched (e.g., using ALE process(s) and/or plasma-based dry etch process(s)) to form a first recess 132 and a second recess 134 in the semiconductor structure 102. The first recess 132 may be an ALE defined recess. The second recess 134 may be an ALE defined recess. The semiconductor structure 102 may include a mesa 136 defined between the first recess 132 and the second recess 134. The semiconductor structure 102 may include a ledge 133 at the bottom of the first recess 132. The semiconductor structure 102 may include a ledge 135 at the bottom of the second recess 134. In some examples, the first recess 132 and/or the second recess 134 may extend at least partially through the cap layer 118. In some examples, the recess 132 and/or the recess 134 may extend through the cap layer 118 and at least partially through the second confining layer 116. The first recess 132 and/or the second recess 134 may extend a depth below the surface of semiconductor structure of about 125 Angstroms or more, such as about 250 Angstroms or more, such as in a range of about 125 Angstroms to about 750 Angstroms, such as in a range of about 250 Angstroms to about 500 Angstroms.

The implanted region 120.1 may be formed beneath the first recess 132 (e.g., beneath the ledge 133) of the semiconductor structure 102. The implanted region 120.1 may extend into the buried channel layer 114. The implanted region 120.2 may be formed beneath the second recess 134 (e.g., beneath the ledge 135) of the semiconductor structure 102. The implanted region 120.2 may extend into the buried channel layer 114.

The source contact 122 may be formed in the first recess 132 on the implanted region 120.1. The source contact 122 may at least partially fill the first recess 132 or may extend above the first recess 132. The drain contact 124 may be formed in the second recess 134 on the implanted region 120.2. The drain contact 124 may at least partially fill the second recess 134 or may extend above the recess 134.

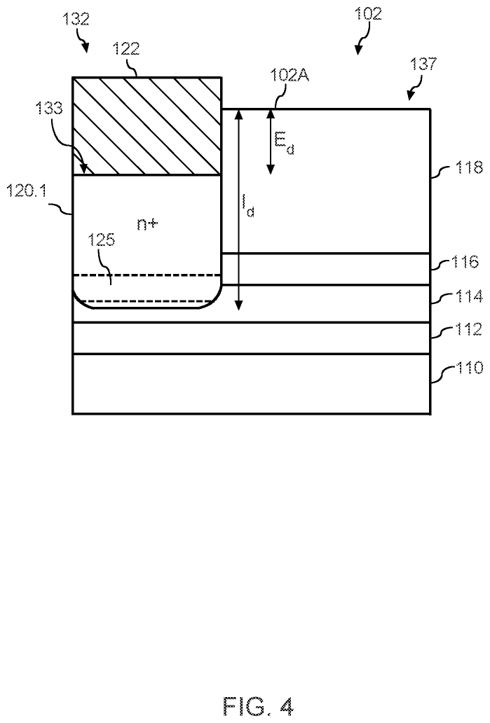

FIG. 4 depicts a close-up cross-sectional view of an example implanted region, such as implanted region 120.1 in the semiconductor structure 102 of the HEMT device 100 of FIG. 3 according to example embodiments of the present disclosure. FIG. 4 is intended to represent structures for identification and description and is not intended to represent the structures to physical scale.

The implanted region 120.1 is beneath the first recess 132 and the ledge 133 of the semiconductor structure 102. The first recess 132 may extend to an etch depth Ed in the semiconductor structure 102. The etch depth Ed may be about 125 Angstroms or more, such as about 250 Angstroms or more, such as in a range of about 125 Angstroms to about 750 Angstroms, such as in a range of about 250 Angstroms to about 500 Angstroms.

The implanted region 120.1 includes a distribution of implanted dopants of a first conductivity type extending into the buried channel layer 114. The implanted dopants may be, for instance, silicon, germanium, sulfur, or oxygen ions. The implanted region 120.1 may have a distribution of implanted dopants that extends to a depth Id from the surface 102A of the semiconductor structure (e.g., the surface of the mesa 136). The depth Id may be about 275 Angstroms or greater, such as about 500 Angstroms or greater, such as in a range of about 275 Angstroms to about 1000 Angstroms. The distribution of implanted dopants may extend through the cap layer 118, the second confining layer 116 and to the buried channel layer 114. In some embodiments, the distribution of implanted dopants may extend into the first confining layer 112 (back barrier layer) and/or into the buffer layer 110 of the semiconductor structure.

The implanted region 120.1 may have a peak dopant concentration of 1×10¹⁸ ions/cm³ or greater. For example, in some embodiments, the dose and energy of the implants may be selected to provide a peak dopant concentration of about 5×10²⁰ ions/cm³ in the implanted region 120.1. The distribution of implanted dopants in the implanted region 120.1 may have its peak dopant concentration at a depth in the implanted region 120.1 close to the buried channel layer 114 of the semiconductor structure 102. For instance, the peak dopant concentration may be in a region 125 within the implanted region 120.1. The region 125 may be within 50 Angstroms or less of the buried channel layer 114. In some examples, the region 125 may be within the buried channel layer 114. In some examples, the distribution of implanted dopants may provide a substantially uniform concentration of implanted dopants throughout the implanted region 120.1 of the semiconductor structure 102.

As shown in FIG. 4, an electrode (e.g., the source contact 122) is formed on the implanted region 120.1 in the first recess 132. The electrode may form an ohmic contact with the implanted region 120.1. The implanted dopants within the implanted region 120.1 may provide a low resistive path between the ohmic source contact 122 and the buried channel layer 114. For instance, the implanted region may have a dopant concentration such that the implanted region 120.1 has a resistivity in a range of about 0.2 Ohms-mm or less.

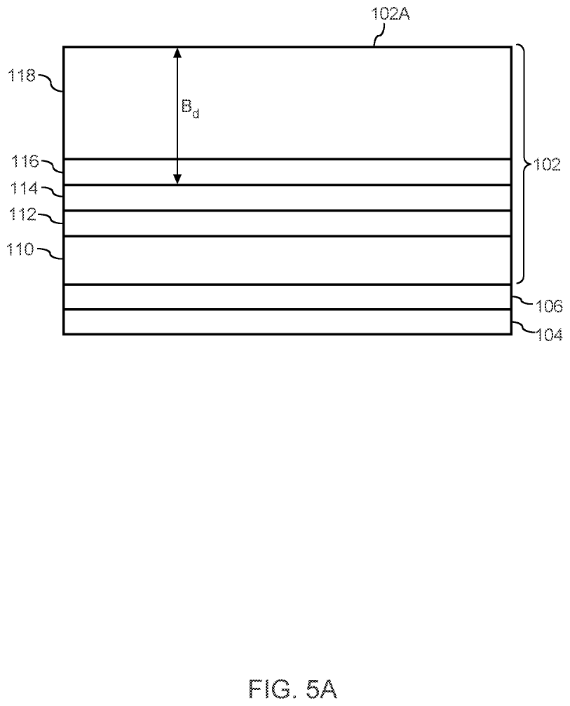

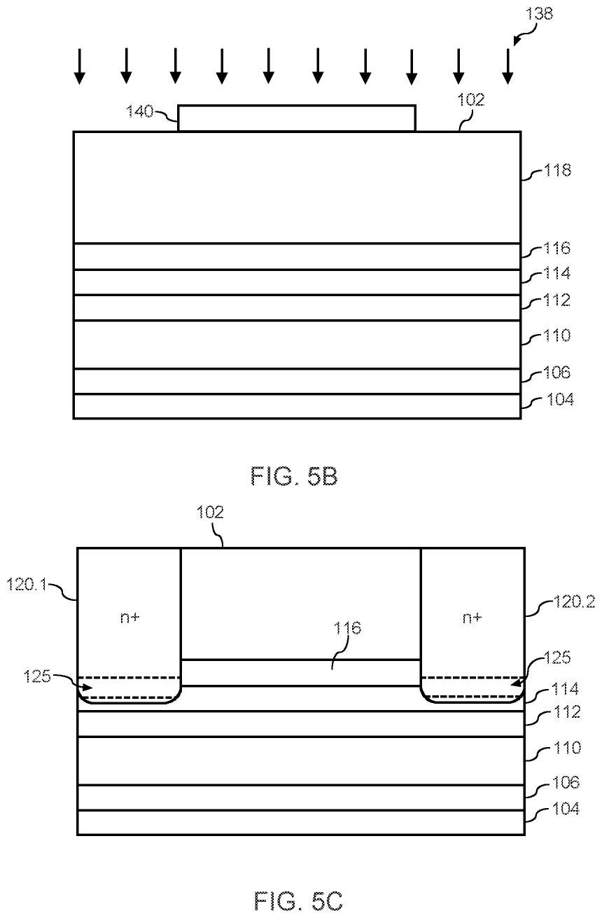

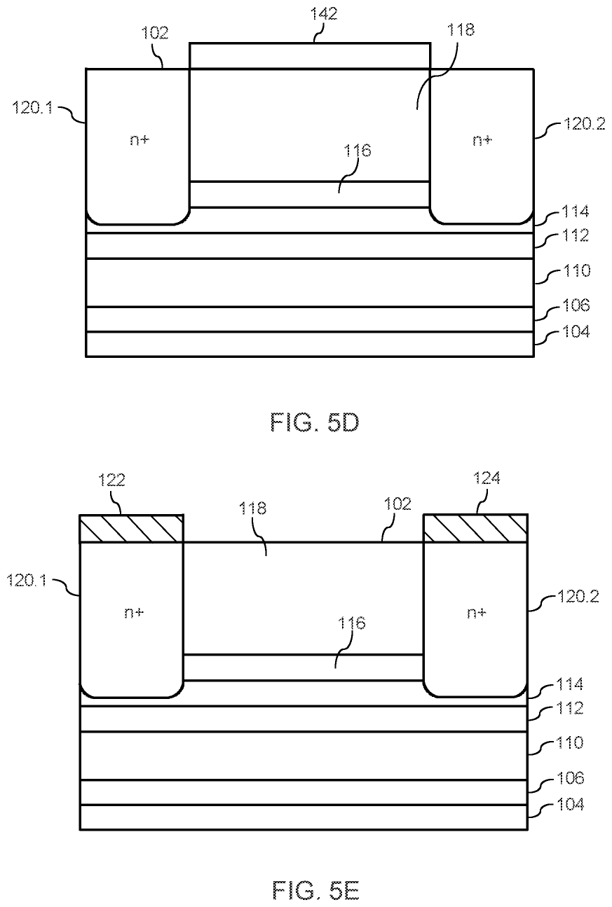

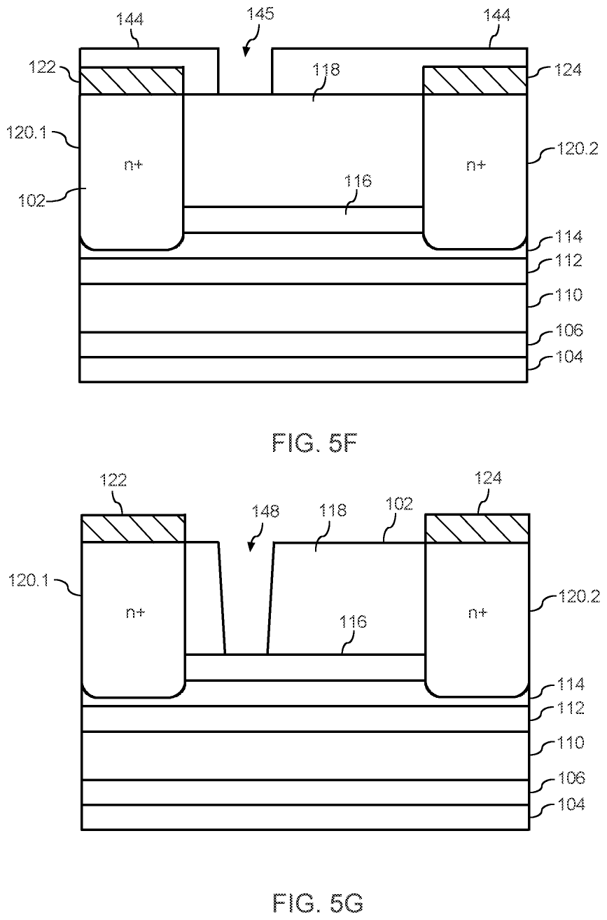

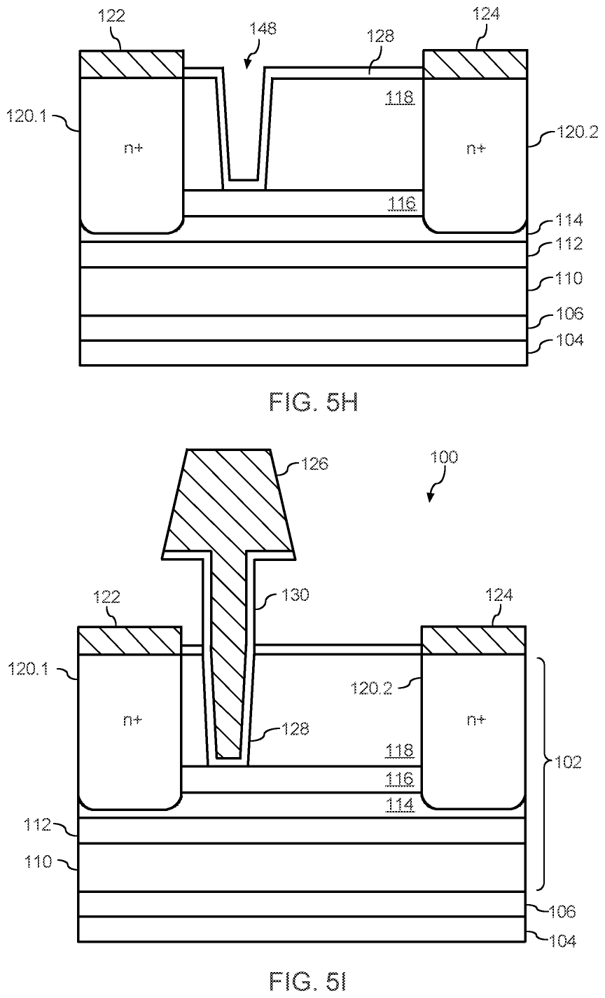

FIGS. 5A-5I are cross-sectional views illustrating aspects of fabrication of semiconductor devices, such as the HEMT device 100 of FIG. 1, according to example embodiments of the present disclosure. FIGS. 5A-5I are intended to represent structures for identification and description and are not intended to represent the structures to physical scale. FIGS. 5A-5I depict example process steps for purposes of illustration and discussion. Those of ordinary skill in the art, using the disclosures provided herein, will understand that the methods described in the present disclosure may be adapted, modified, include steps not illustrated, omitted, and/or rearranged without deviating from the scope of the present disclosure.

In FIG. 5A, a semiconductor structure 102 is formed on the substrate 104 and/or the optional nucleation layer 106. The semiconductor structure 102 may be an N-polar Group III-nitride. The semiconductor structure 102 may be epitaxially grown on the substrate 104 and/or nucleation layer 106. The semiconductor structure 102 may include a buried layer (e.g., channel layer 114) that is buried deeply below the top surface of the semiconductor structure. The buried layer may be, for instance, at a depth Bd of about 275 Angstroms or greater from the top surface of the semiconductor structure, such as about 500 Angstroms or greater, such as in a range of about 275 Angstroms to about 1000 Angstroms. The semiconductor structure 102 and/or the nucleation layer 106 may be deposited by MOCVD or by other techniques known to those of skill in the art, such as MBE or HYPE.

In the example of FIG. 5A, the semiconductor structure 102 is a multilayer N-polar Group III-nitride semiconductor structure. The semiconductor structure 102 may include, for instance, a buffer layer 110, a first confining layer 112, a channel layer 114, a second confining layer 116, and a cap layer 118. Details concerning these example layers are described above with reference to FIG. 1.

Referring to FIG. 5B, a mask 140 is formed on the semiconductor structure 102. The mask 140 may include photoresist or any other suitable mask material, such as SiN and/or SiO₂. The mask may have a thickness selected to block implanted ions during an ion implantation process.

Referring to FIG. 5B, windows are opened in the mask 140 to expose surface portions of the semiconductor structure 102. An ion implantation process is performed to implant ions 138 through the windows into the semiconductor structure 102 such that at least a portion of the implanted ions are implanted through the semiconductor structure 102 and come to rest within the buried layer (e.g., channel layer 114) as shown in FIG. 5C. The implanted ions may form a distribution profile having a peak dopant concentration in a region 125 within 50 Angstroms of the channel layer 114, such as within the channel layer 114. Accordingly, as shown in FIG. 5C, implanted regions 120.1 and 120.2 may be formed extending at least partially through the semiconductor structure 102 and into the channel layer 114. The implanted regions 120.1 and 120.2 may extend to a depth below the surface 102A of the semiconductor structure. The depth may be 275 Angstroms or greater, such as 500 Angstroms or greater, such as in a range of 275 Angstroms to 1000 Angstroms.

The implant conditions may be selected to provide implant regions 120.1 and 120.2 having a peak dopant concentration of 1×10¹⁸ ions/cm³ or greater. For example, in some embodiments, the dose and energy of the implants may be selected to provide a peak dopant concentration of about 5×10²⁰ ions/cm³ in the implanted region 120.1 and 120.2. The implant conditions may also be selected to provide a distribution of implanted dopants having a substantially uniform concentration throughout the implanted regions 120.1 and 120.2. For instance, the implant process may include multiple implant steps to provide a relatively uniform profile of implanted dopants throughout the implanted region 120.1 and 120.2. As such, the number of implant steps may depend on the thickness of the semiconductor structure 102 and the depth of the implanted regions 120.1 and 120.2. For example, the implant process may include a first implant step performed under a first set of implant conditions, and a subsequent implant step performed under a second set of implant conditions. However, more than two implant steps may be performed to provide the implanted regions 120.1 and 120.2.

In some embodiments, the ion implantation process may be performed at room temperature. The implant energies and/or doses may be selected to provide an implant profile that achieves a desired sheet resistivity and/or permits fabrication of low resistivity ohmic contacts to the buried layer (e.g., the channel layer 114). In order to form n-type implanted regions 120.1 and 120.2 in a Group III-nitride layer, the implanted dopants may include silicon, germanium, sulfur, and/or oxygen ions.

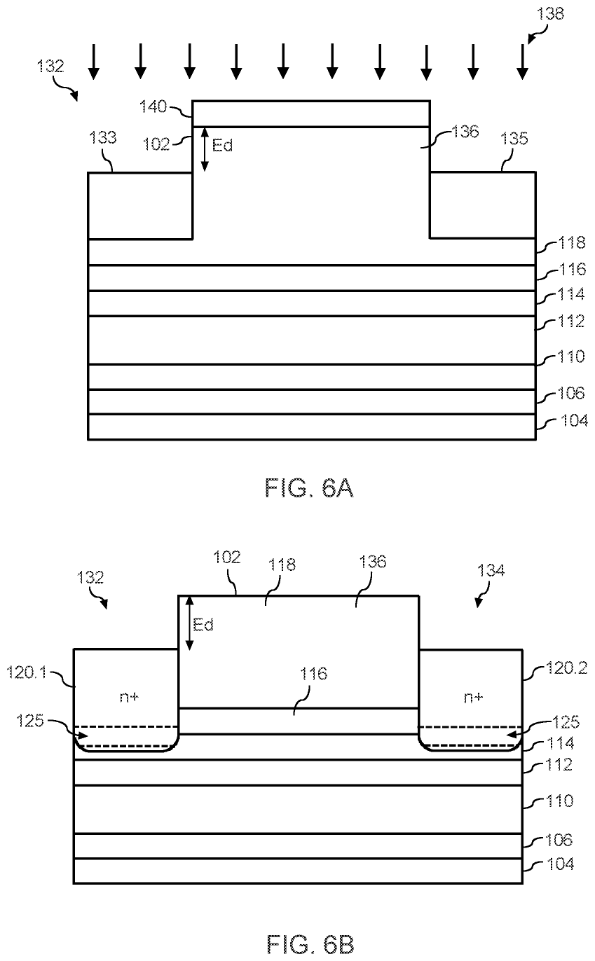

In some embodiments, the semiconductor structure 102 may be etched to form recesses and a mesa structure prior to the ion implantation process. For instance, as shown in FIG. 6A an etch process may be performed to remove exposed portions of the semiconductor structure 102 to form a first recess 132 and as second recess 134. The etch process may etch the semiconductor structure to an etch depth Ed. The etch depth Ed may be in a range of about 125 Angstroms or more, such as about 250 Angstroms or more, such as in a range of about 125 Angstroms to about 750 Angstroms, such as in a range of about 250 Angstroms to about 500 Angstroms. In some examples, the etch process may be an ALE process. In some examples, the etch process may be a plasma-based dry etch process. The plasma-based dry etch process may use a pulsed plasma or provide continuous exposure to plasma.

After the etch process, the semiconductor structure 102 may include a mesa 136 defined between the first recess 132 and the second recess 134. The semiconductor structure 102 may include a ledge 133 at the bottom of the first recess 132. The semiconductor structure 134 may include a ledge 135 at the bottom of the second recess 134. In some examples, the first recess 132 and/or the second recess 134 may extend at least partially through the cap layer 118. In some examples, the first recess 132 and/or the second recess 134 may extend through the cap layer 118 and at least partially through the second confining layer 116.

An ion implantation process is performed to implant ions 138 through the first recess 132 and the second recess 134 into the semiconductor structure 102 such that at least a portion of the implanted ions are implanted through the semiconductor structure 102 and come to rest within the buried layer (e.g., channel layer 114) as shown in FIG. 6B. The implanted ions may form a distribution profile having a peak dopant concentration in a region 125 within 50 Angstroms of the channel layer 114, such as within the channel layer 114. Accordingly, as shown in FIG. 6B, implanted regions 120.1 and 120.2 may be formed extending at least partially through the semiconductor structure 102 and into the channel layer 114. The implanted regions 120.1 and 120.2 may extend to a depth below the surface 102A of the semiconductor structure. The depth may be 275 Angstroms or greater, such as 500 Angstroms or greater, such as in a range of 275 Angstroms to 1000 Angstroms.

The implant conditions may be selected to provide implant regions 120.1 and 120.2 having a peak dopant concentration of 1×10¹⁸ ions/cm³ or greater. For example, in some embodiments, the dose and energy of the implants may be selected to provide a peak dopant concentration of about 5×10²⁰ ions/cm³ in the implanted region 120.1 and 120.2. The implant conditions may also be selected to provide a distribution of implanted dopants having a substantially uniform concentration throughout the implanted regions 120.1 and 120.2. For instance, the implant process may include multiple implant steps to provide a relatively uniform profile of implanted dopants throughout the implanted region 120.1 and 120.2. As such, the number of implant steps may depend on the thickness of the semiconductor structure 102 and the depth of the implanted regions 120.1 and 120.2. For example, the implant process may include a first implant step performed under a first set of implant conditions, and a subsequent implant step performed under a second set of implant conditions. However, more than two implant steps may be performed to provide the implanted regions 120.1 and 120.2.

In some embodiments, the ion implantation process may be performed at room temperature. The implant energies and/or doses may be selected to provide an implant profile that achieves a desired sheet resistivity and/or permits fabrication of low resistivity ohmic contacts to the buried layer (e.g., the channel layer 114). In order to form n-type implanted regions 120.1 and 120.2 in a Group III-nitride layer, the implanted ions may include silicon, germanium, sulfur, and/or oxygen ions.

After formation of the implanted regions 120.1 and 120.2a as shown in either FIG. 5C or FIG. 6B, the implanted dopants may be activated by an activation anneal. The mask 140 may be removed prior to the implant activation anneal, for example, by way of a photoresist strip process and/or an etch process. However, the activation anneal may be performed with the mask 140 in place.

The activation anneal may be performed in an inert atmosphere including, for example, N₂ and/or Ar. The activation anneal may be performed at a temperature sufficient to activate the implanted dopant ions but less than a temperature at which the semiconductor structure 102 deteriorates. In some embodiments, a protective layer (e.g., a SiN protective layer or other suitable protective layer) may be formed over the semiconductor structure. The protective layer may inhibit damage to the underlying semiconductor structure during high temperature process steps.

In some embodiments, the activation anneal may be performed at a temperature of about 1000° C. to about 1300° C. The activation anneal may be performed in-situ and/or in a separate annealing chamber. The activation anneal may be performed for at least about 30 seconds or more, depending on the anneal temperature. For example, a rapid thermal anneal (RTA) at about 1300° C. may be performed for about 30 seconds, while a furnace anneal at about 1000° C. may be performed for about 30 minutes. The particular selection of activation times and temperatures may vary depending on the type of materials involved and the particular implant conditions employed. In particular embodiments, the anneal time may be in the range of about 30 seconds to about 30 minutes.

Referring now to FIG. 5D, a second mask 142 is formed on the semiconductor structure, and windows are opened in the second mask 142 for the formation of electrodes on the implanted regions 120.1 and 120.2. The windows may be formed utilizing a low damage etch with respect to the semiconductor structure 102 to expose the underlying implanted regions 120.1 and 120.2 of the semiconductor structure 102. Examples of low damage etch techniques include etching techniques other than reactive ion etching, such as inductively coupled plasma or electron cyclotron resonance (ECR) or downstream plasma etching with no DC component to the plasma, or a selective wet etch.

As shown in FIG. 5E, metal may be deposited on the exposed implanted regions 120.1 and 120.2 of the semiconductor structure 102, for example by evaporation, to provide the electrodes, which are illustrated in FIG. 5D as ohmic source contact 122 and ohmic drain contact 124. Suitable contact metals may include, for instance, titanium (Ti), tungsten (W), titanium tungsten (TiW), silicon (Si), titanium tungsten nitride (TiWN), tungsten silicide (WSi), rhenium (Re), niobium (Nb), Ni, gold (Au), aluminum (Al), tantalum (Ta), molybdenum (Mo), NiSiₓ, titanium silicide (TiSi), titanium nitride (TiN), tungsten silicon nitride (WSiN), platinum (Pt) and the like.

In some embodiments, the deposited metal may be annealed at a relatively high temperature to provide the ohmic source contact 122 and the ohmic drain contact 124. For example, the anneal may be an anneal at a temperature of greater than about 900° C. in an atmosphere of an inert gas such as N₂ or Ar. Through the use of an ohmic contact anneal, the resistance of the ohmic source contact 122 and the ohmic drain contact 124 may be reduced from a relatively high resistance to about 1 ohm-mm or less. As with the implant activation anneal, a protective layer may be used during the high temperature process steps to inhibit damage to the semiconductor structure 102. It will be appreciated, however, that due to the presence of the implanted regions 120.1 and 120.2 in the semiconductor structure 102, it may not be necessary to anneal the deposited metal in order to form an ohmic contact. That is, the metal may be ohmic as deposited. In addition, since the ohmic source contact 122 and the ohmic drain contact 124 are formed on the implanted regions 120.1 and 120.2, the ohmic source contact 122 and the ohmic drain contact 124 may have a lower resistivity than ohmic contacts formed on non-implanted regions. Thus, the on-resistance of devices formed according to some embodiments of the present disclosure may be reduced.

In FIG. 5F, a third mask 144 may be formed on the semiconductor structure 102 and over the ohmic source contact 122 and ohmic drain contact 124. The third mask 144 may include photoresist or any other suitable mask material, such as SiN and/or SiO₂. A window 145 may be formed in the third mask 144 exposing a portion of the semiconductor structure 102.

In FIG. 5G, an etch process is conducted on the exposed portion of the semiconductor structure 102 to form a trench 148 in the semiconductor structure 102. The trench 148 may extend at least partially through or entirely through the cap layer 118 of the semiconductor structure 102. For instance, the trench 148 may extend through the thickness of the cap layer 118 to a depth in a range of about 250 Angstroms to about 1000 Angstroms. The etch process used to form the trench 148 may be an ALE etch process such that the trench 148 is an ALE defined trench. Other etch processes may be used without deviating from the scope of the present disclosure, such as plasma-based dry etch process (e.g., using a pulsed plasma or a continuous plasma).

In FIG. 5H, a passivation layer 128 is deposited using a deposition process. The passivation layer 128 may be, for instance, SiN. The passivation layer 128 may be another suitable dielectric material, such as SiO₂, MgOx, MgNx, ZnO, SiNx, SiOx or other dielectric material. The passivation layer 128 may line the trench 148. The passivation layer 128 may be deposited using an ALD process such that the passivation layer 128 is an ALD defined passivation layer. Other suitable deposition processes may be used without deviating from the scope of the present disclosure. For instance, the passivation layer 128 may be deposited using an MOCVD process or a sputter deposition process.

FIG. 5I, metal may be deposited to form a gate contact 126 in the trench 148. The gate contact 126 may be a T-shaped gate or gamma gate, the formation of which is discussed by way of example in U.S. Pat. Nos. 8,049,252, 7,045,404, and 8,120,064, the disclosures of which are incorporated by reference herein. The material of the gate contact 126 may be chosen based on the composition of the second confining layer 116. Materials capable of making a contact (e.g., a Schottky contact) to a Group III-nitride based semiconductor material may be used, such as, for example, nickel (Ni), platinum (Pt), nickel silicide (NiSiₓ), copper (Cu), palladium (Pd), chromium (Cr), tungsten (W) and/or tungsten silicon nitride (WSiN).

As further shown in FIG. 5I, a passivation layer 130 may be formed on the gate contact 126. For instance, the passivation layer 130 may be formed on the side walls and underside of the T-shaped gate contact 126. The passivation layer 130 may be, for instance, SiN. The passivation layer 130 may be another suitable dielectric material, such as SiO₂, MgOx, MgNx, ZnO, SiNx, SiOx or other dielectric material. The passivation layer 130 may be deposited using an ALD process. Other suitable deposition processes may be used without deviating from the scope of the present disclosure. For instance, the passivation layer 130 may be deposited using an MOCVD process or a sputter deposition process.

Example aspects of the present disclosure are provided in the following paragraphs, the example of which may be combined to form various different embodiments of the present disclosure.

One example aspect of the present disclosure is directed to a semiconductor device. The semiconductor device includes a semiconductor structure having a buried layer at a depth of about 275 Angstroms or greater from a surface of the semiconductor structure. The semiconductor device includes an implanted region extending at least partially through the semiconductor structure and into the buried layer. The implanted region includes a distribution of implanted dopants of a first conductivity type extending into the buried layer. The semiconductor device includes an electrode on the implanted region.

In some examples, the buried layer may be at a depth of about 500 Angstroms or greater from the surface of the semiconductor structure. In some examples, the buried layer may be at a depth in a range of about 275 Angstroms to about 1000 Angstroms from the surface of the semiconductor structure.

In some examples, the distribution of implanted dopants of the first conductivity type in the implanted region has a peak dopant concentration of implanted dopants at a depth in the implanted region within about 50 Angstroms or less of the buried layer.

In some examples, a peak dopant concentration of implanted dopants may be at least about 1×10¹⁸ ions/cm³. In some examples, the implanted dopants may include silicon, germanium, sulfur, or oxygen ions.

In some examples, the electrode includes an ohmic contact.

In some examples, the buried layer may include a Group III-nitride layer. In some examples, the semiconductor structure may include an N-polar Group III-nitride semiconductor structure comprising an N-face at the surface of the semiconductor structure.

In some examples, the semiconductor structure may include a first confining layer on a first surface of the buried layer and a second confining layer on a second surface of the buried layer. In some examples, the semiconductor structure may further include a cap layer on the first confining layer. The implanted region may extend through the cap layer and the first confining layer. The electrode may extend at least partially through the cap layer. The cap layer may have a thickness in a range of about 250 Angstroms to about 1000 Angstroms. In some examples, the semiconductor device may include a 2DEG at an interface between the buried layer and the second confining layer.

In some examples, the first confining layer may include Al_{w}Ga_{1-w}N, where w is in a range of about 0.1 to about 0.4; the buried layer may include AlₓGa₁₋ₓN, where x is less than about 0.1; the second confining layer may include Al_{y}Ga_{1-y}N, where y is in a range of about 0.1 to about 0.4; and the cap layer may include Al_{z}Ga_{1-z}N, where w is in less than about 0.1.

In some examples, the semiconductor device may include a mesa and a recess. The implanted region may be beneath the recess. The recess may have a depth in a range of about 125 Angstroms to about 750 Angstroms.

In some examples, the semiconductor device may be on a silicon carbide substrate. In some examples, the semiconductor device is a high electron mobility transistor device.

Another example aspect of the present disclosure is directed to a transistor device. The transistor device includes an N-polar Group III-nitride semiconductor structure having an N face at a surface of the semiconductor structure. The semiconductor structure includes a buried channel layer. The semiconductor structure includes a confining layer on a first surface of the buried channel layer. The semiconductor structure includes a barrier layer on a second surface of the buried channel layer. The transistor device includes an implanted region extending at least partially through the confining layer and into the buried channel layer. The implanted region includes a distribution of implanted dopants of a first conductivity type extending into the buried channel layer. The implanted region includes an electrode on the implanted region.

In some examples, the implanted region may extend to a depth of about 275 Angstroms or greater into the N-polar Group III-nitride semiconductor structure. In some examples, the implanted region may extend to a depth of about 500 Angstroms or greater from the surface of the N-polar Group III-nitride semiconductor structure. In some examples, the implanted region may extend to a depth in a range of about 275 Angstroms to about 1000 Angstroms from the surface of the N-polar Group III-nitride semiconductor structure.

In some examples, the distribution of implanted dopants of the first conductivity type in the implanted region has a peak dopant concentration of implanted dopants at a depth in the implanted region within about 50 Angstroms or less of the buried channel layer. In some examples, the peak dopant concentration of implanted dopants may be at least about 5×10²⁰ ions/cm³. In some examples, the implanted dopants may include silicon, germanium, sulfur, or oxygen ions.

In some examples, the electrode may include an ohmic contact. The ohmic contact may be a source contact or a drain contact for the transistor device.

In some examples, the transistor device may include a cap layer on the confining layer. The cap layer may include an N-polar Group III-nitride having an N-face at a surface of the cap layer. The cap layer may have a thickness in a range of about 250 Angstroms to about 1000 Angstroms. The implanted region may extend at least partially through the cap layer.

In some examples, the transistor device may include a recess in the cap layer. The implanted region may be beneath the recess. The recess may have a depth in a range of about 125 Angstroms to about 750 Angstroms. The recess may be an atomic layer etch (ALE) defined recess.

In some examples, the confining layer and the barrier layer may include AlGaN. In some examples, the confining layer may include SLAIN or ScAlGaN. In some examples, the barrier layer may include ScAlN or ScAlGaN. In some examples, the cap layer may include GaN. In some examples, the buried channel layer may include GaN.

In some examples, the transistor device may include a gate contact. In some examples, the gate contact may extend at least partially through the cap layer. In some examples, the gate contact may be at least partially located in an atomic layer etch (ALE) defined trench in the cap layer.

In some examples, the transistor device may include a passivation layer. The passivation layer may include SiN. The passivation layer may be an atomic layer deposition (ALD) defined passivation layer.

In some examples, the transistor device is a high electron mobility transistor device. In some examples, the transistor device comprises a silicon carbide substrate.

In some examples, the transistor device may be operable at frequencies of up to about 150 GHz. For instance, the transistor device may be operable at a frequency in a range of about 10 GHz to about 150 GHz, such as in a range of about 30 GHz to about 150 GHz, such as in a range of about 50 GHz to about 150 GHz. In some examples, the transistor device may have a power density of up to 10 W/mm or greater in these frequency ranges, such as a power density in a range of 2.5 W/mm to about 12 W/mm.

Another example aspect of the present disclosure is directed to a transistor device. The transistor device includes an N-polar Group III-nitride semiconductor structure having an N-face at a surface of the semiconductor structure. The transistor device includes a source contact. The transistor device includes a drain contact. The transistor device includes a gate contact. The N-polar Group III-nitride semiconductor structure includes a barrier layer, a channel layer on the barrier layer, a confining layer on the channel layer, and a cap layer on the confining layer. The transistor device includes an atomic layer etch (ALE) defined recess in the N-polar Group III-nitride semiconductor structure.

In some examples, the transistor device may include an implanted region formed in the N-polar Group III-nitride semiconductor structure below the ALE defined recess. The implanted region may include a distribution of implanted dopants of a first conductivity type extending into the channel layer.

In some examples, the channel layer is at a depth of about 275 Angstrom or greater from the surface of the N-polar Group III-nitride semiconductor structure. In some examples, the channel layer is at a depth of about 500 Angstroms or greater from the surface of the N-polar Group III-nitride semiconductor structure. In some examples, the channel layer is at a depth in a range of about 275 Angstroms to about 1000 Angstroms from the surface of the N-polar Group III-nitride semiconductor structure. In some examples, at least one of the source contact or the drain contact is an ohmic contact on the implanted region.

In some examples, the distribution of implanted dopants of the first conductivity type in the implanted region may have a peak dopant concentration of implanted dopants at a depth in the implanted region within about 50 Angstroms or less of the channel layer.

In some examples, the gate contact is formed in an ALE defined trench.

In some examples, the transistor device may include one or more passivation layers. In some examples, the one or more passivation layers may include an atomic layer deposition (ALD) defined passivation layer.

In some examples, the transistor device may be operable at frequencies of up to about 150 GHz. For instance, the transistor device may be operable at a frequency in a range of about 10 GHz to about 150 GHz, such as in a range of about 30 GHz to about 150 GHz, such as in a range of about 50 GHz to about 150 GHz. In some examples, the transistor device may have a power density of up to 10 W/mm or greater in these frequency ranges, such as a power density in a range of 2.5 W/mm to about 12 W/mm.

Another example aspect of the present disclosure is directed to a method of forming a semiconductor device. The method includes forming a semiconductor structure having a buried layer and one or more confining layers. The buried layer is at a depth of about 275 Angstroms or greater (e.g., 500 Angstroms or greater) from a surface of the semiconductor structure. The method includes implanting dopants into the semiconductor structure to form an implanted region in the semiconductor structure. The implanted region extends at least partially through the semiconductor structure and into the buried layer. The implanted region includes a distribution of implanted dopants of a first conductivity type extending into the buried layer.

In some examples, the buried layer may be at a depth of 500 Angstroms or greater from the surface of the semiconductor structure. In some examples, the buried layer may be at a depth in a range of 275 Angstroms to 1000 Angstroms from the surface of the semiconductor structure.

In some examples, the method may include forming an electrode on the implanted region. In some examples, the electrode may be an ohmic contact on the implanted region.

In some examples, the distribution of implanted dopants of the first conductivity type in the implanted region may have a peak dopant concentration of implanted dopants at a depth in the implanted region within about 50 Angstroms or less of the buried layer.

In some examples, a peak dopant concentration of implanted dopants may be at least about 5×10²⁰ ions/cm³. In some examples, the implanted dopants may include silicon, germanium, sulfur, or oxygen ions.

In some examples, the semiconductor structure is an N-polar Group III-Nitride semiconductor having an N-face at the surface of the semiconductor structure.

In some examples, the method may include forming a recess in the semiconductor structure prior to implanting dopants. In some examples, implanting dopants may include implanting dopants into the semiconductor structure to form an implanted region in the semiconductor structure beneath the recess. In some examples, the recess is an atomic layer etch (ALE) defined trench.

In some examples, the method may include forming a passivation layer using atomic layer deposition (ALD).

While the present subject matter has been described in detail with respect to specific example embodiments thereof, it will be appreciated that those skilled in the art, upon attaining an understanding of the foregoing may readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

What is claimed is:

1. A semiconductor device, comprising:
a semiconductor structure comprising a buried layer at a depth of about 275 Angstroms or greater from a surface of the semiconductor structure;
an implanted region extending at least partially through the semiconductor structure and into the buried layer, the implanted region comprising a distribution of implanted dopants of a first conductivity type extending into the buried layer; and
an electrode on the implanted region.

2. The semiconductor device of claim 1, wherein the buried layer is at a depth of about 500 Angstroms or greater from the surface of the semiconductor structure.

3. The semiconductor device of claim 1, wherein the distribution of implanted dopants of the first conductivity type in the implanted region has a peak dopant concentration of implanted dopants at a depth in the implanted region within about 50 Angstroms or less of the buried layer.

4. The semiconductor device of claim 1, wherein a peak dopant concentration of implanted dopants is at least about 1×10¹⁸ ions/cm³.

5. The semiconductor device of claim 1, wherein the implanted dopants comprise silicon, germanium, sulfur, or oxygen ions.

6. The semiconductor device of claim 1, wherein the electrode comprises an ohmic contact.

7. The semiconductor device of claim 1, wherein the buried layer comprises a Group III-nitride layer.

8. The semiconductor device of claim 1, wherein the semiconductor structure comprises an N-polar Group III-nitride semiconductor structure comprising an N-face at the surface of the semiconductor structure.

9. The semiconductor device of claim 1, wherein the semiconductor structure comprises a first confining layer on a first surface of the buried layer and a second confining layer on a second surface of the buried layer.

10. The semiconductor device of claim 9, wherein the semiconductor structure further comprises a cap layer on the first confining layer.

11. The semiconductor device of claim 10, wherein the cap layer has a thickness in a range of about 250 Angstroms to about 1000 Angstroms.

12. The semiconductor device of claim 10, wherein:
wherein the first confining layer comprises Al_{w}Ga_{1-w}N, where w is in a range of about 0.1 to about 0.4;
wherein the buried layer comprises AlₓGa₁₋ₓN, where x is less than about 0.1.
wherein the second confining layer comprises Al_{y}Ga_{1-y}N, where y is in a range of about 0.1 to about 0.4; and
wherein the cap layer comprises Al_{z}Ga_{1-z}N, where w is in less than about 0.1.

13. The semiconductor device of claim 1, wherein the semiconductor device comprises a mesa and a recess.

14. The semiconductor device of claim 13, wherein the implanted region is beneath the recess.

15. The semiconductor device of claim 1, wherein the semiconductor device is on a silicon carbide substrate.

16. The semiconductor device of claim 1, wherein the semiconductor device is a high electron mobility transistor device.

17. A transistor device, comprising:
an N-polar Group III-nitride semiconductor structure having an N face at a surface of the semiconductor structure, the semiconductor structure comprising:
a buried channel layer;
a confining layer on a first surface of the buried channel layer;
a barrier layer on a second surface of the buried channel layer; and
an implanted region extending at least partially through the confining layer and into the buried channel layer, the implanted region comprising a distribution of implanted dopants of a first conductivity type extending into the buried channel layer; and
an electrode on the implanted region.

18. The transistor device of claim 17, wherein the implanted region extends to a depth of about 275 Angstroms or greater into the N-polar Group III-nitride semiconductor structure.

19. The transistor device of claim 17, wherein the distribution of implanted dopants of the first conductivity type in the implanted region has a peak dopant concentration of implanted dopants at a depth in the implanted region within about 50 Angstroms or less of the buried channel layer.

20. The transistor device of claim 17, wherein the electrode comprises an ohmic source contact or an ohmic drain contact for the transistor device.

21. The transistor device of claim 17, further comprising a cap layer on the confining layer, wherein the cap layer has a thickness in a range of about 250 Angstroms to about 1000 Angstroms.

22. The transistor device of claim 21, wherein the transistor device further comprises a recess in the cap layer, wherein the implanted region is beneath the recess.

23. The transistor device of claim 22, wherein the recess has a depth in a range of about 125 Angstroms to about 750 Angstroms.

24. The transistor device of claim 22, wherein the recess is an atomic layer etch (ALE) defined recess.

25. The transistor device of claim 17, wherein the confining layer or the barrier layer comprises ScAlN or ScAlGaN.

26. The transistor device of claim 21, wherein further comprising a gate contact is at least partially located in an atomic layer etch (ALE) defined trench in the cap layer.

27. The transistor device of claim 17, wherein further comprising an atomic layer deposition (ALD) defined passivation layer.

28. The transistor device of claim 17, wherein the transistor device is a high electron mobility transistor device.

29. The transistor device of claim 17, where in the transistor device is operable at frequencies in a range of about 10 GHz to about 150 GHz.

30. A method of forming a semiconductor device, comprising:
forming a semiconductor structure comprising a buried layer and one or more confining layers, the buried layer being at a depth of about 275 Angstroms or greater from a surface of the semiconductor structure; and
implanting dopants into the semiconductor structure to form an implanted region in the semiconductor structure, the implanted region extending at least partially through the semiconductor structure and into the buried layer, the implanted region comprising a distribution of implanted dopants of a first conductivity type extending into the buried layer.
